(19) United States
(12) Patent Application Publication
(10) Pub. No.: US 2026/0040855 A1
(43) Pub. Date: Feb. 5, 2026

(54) LOCAL DEFORMATION AND STRESS CONTROL IN DEVICE MANUFACTURING

(71) Applicant: Applied Materials, Inc., Santa Clara, CA (US)

(72) Inventors: San-Kuei Lin, Los Gatos, CA (US); Pradeep Kumar Subrahmanyan, San Jose, CA (US)

(21) Appl. No.: 19/252,404

(22) Filed: Jun. 27, 2025

Related U.S. Application Data
(60) Provisional application No. 63/678,393, filed on Aug. 1, 2024.

(51) Int. Cl. H01L 21/311; H01L 21/027; H01L 21/66

(52) U.S. Cl. CPC H01L 21/31144; H01L 21/0274; H01L 22/12

(57) ABSTRACT

Disclosed systems and techniques are directed to improvement of semiconductor manufacturing. In one embodiment, the disclosed techniques include forming a deformation-accommodating layer (DAL) on a target substrate. The target substrate can include a first substrate supporting one or more manufactured features, or a second substrate. The techniques further include removing one or more portions of the DAL, causing the first substrate and the second substrate to form a composite structure, and thinning the first substrate to expose at least a subset of the one or more manufactured features, wherein the one or more portions of the DAL are removed to cause, responsive to the thinning, a deformation of the composite structure.

### RELATED APPLICATIONS

The present application claims the benefit under 35 U.S.C. § 119(e) of U.S. Provisional Patent Application No. 63/678,393, filed Aug. 1, 2024, entitled “LOCAL DEFORMATION AND STRESS CONTROL IN DEVICE MANUFACTURING,” which is incorporated in its entirety by reference herein.

### TECHNICAL FIELD

The disclosure pertains to semiconductor manufacturing, including processing of wafers and devices manufactured thereon.

### BACKGROUND

Modern semiconducting devices, such as processing units, memory devices, light detectors, solar cells, light-emitting semiconductor devices, devices that deploy complementary metal-oxide-semiconductor (CMOS) structures, and the like, are often manufactured on silicon wafers (or other suitable substrates). Wafers may undergo numerous processing operations, such as physical vapor deposition, chemical vapor deposition, etching, photo-masking, polishing, and/or various other operations. In a continuous effort to reduce the cost of semiconductor devices, multi-layer stacks of dies, insulating films, patterned and/or doped semiconducting films, and/or other features are often deposited on a single wafer, resulting in high aspect ratio devices, which are used, e.g., in 3D flash memory devices and other applications. Deposition, patterning, etching, polishing, etc., of stacks of multi-layered structures often result in significant stresses applied to the underlying wafers. Such stresses lead to both an out-of-plane distortion and an in-plane distortion of features supported by the wafers. These distortions result in misalignment of deposited features and can significantly degrade quality of manufactured devices.

### BRIEF DESCRIPTION OF THE DRAWINGS

The present disclosure will be understood more fully from the detailed description given below and from the accompanying drawings of various embodiments of the disclosure.

FIG. 1 illustrates schematically stresses in an example substrate structure that can be mitigated using the techniques of the instant disclosure.

FIGS. 2A-2P illustrate mitigation of local stresses and deformations in complex multi-substrate manufacturing structures, according to at least one embodiment.

FIGS. 3A-3E illustrate schematically a process of correcting a sample deformation using a stress-modification beam applied to the back side of a sample, according to at least one embodiment, according to at least one embodiment.

FIG. 4 illustrates an example Zernike polynomial decomposition of one actual deformation (top left) of a wafer, in arbitrary units, into a paraboloid bow deformation (top right), a saddle deformation (bottom left), and a residual deformation, (bottom right), according to at least one embodiment.

FIG. 5 is a flowchart illustrating an example method of mitigation of local stresses and deformations in complex multi-substrate manufacturing structures, in accordance with at least one embodiment.

FIG. 6 is a flowchart illustrating an example method of determining settings for irradiation by a stress-modification beam, in accordance with at least one embodiment.

FIG. 7 illustrates schematically example protective mask patterns that can be uses for mitigation of local stresses and deformations in complex multi-substrate manufacturing structures, according to at least one embodiment nt.

FIG. 8A-8B illustrates schematically an irradiation system capable of performing irradiation of stress compensation layers, according to at least one embodiment.

FIG. 9 depicts a block diagram of an example computer system capable of supporting operations of the present disclosure, according to at least one embodiment.

### SUMMARY

Disclosed herein, according to one embodiment, is a method that includes forming a deformation-accommodating layer (DAL) on a target substrate, the target substrate including a first substrate supporting one or more manufactured features. or a second substrate. The method further includes removing one or more portions of the DAL, causing the first substrate and the second substrate to form a composite structure, and thinning the first substrate to expose at least a subset of the one or more manufactured features, wherein the one or more portions of the DAL are removed to cause, responsive to the thinning, a deformation of the composite structure to be reduced.

In another embodiment, disclosed is a system that includes a memory and a processing device communicatively coupled to the memory. The processing device is to cause performance of operations that include forming a deformation-accommodating layer (DAL) on a target substrate, the target substrate includes one a first substrate supporting one or more manufactured features or a second substrate. The operations further includes removing one or more portions of the DAL, causing the first substrate and the second substrate to form a composite structure, and thinning the first substrate to expose at least a subset of the one or more manufactured features, wherein the one or more portions of the DAL are removed to cause, responsive to the thinning, a deformation of the composite structure.

In yet another embodiment, disclosed is a semiconductor manufacturing system that includes one or more processing chambers to form a deformation-accommodating layer (DAL) on a target substrate, the target substrate including a first substrate supporting one or more manufactured features or a second substrate. The one or more processing chambers are further to remove one or more portions of the DAL, cause the first substrate and the second substrate to form a composite structure, and thin the first substrate to expose at least a subset of the one or more manufactured features, wherein the one or more portions of the DAL are removed to cause, responsive to the thinning, a deformation of the composite structure.

### DETAILED DESCRIPTION

Modern technology often aims to maximize chip area utilization by manufacturing three-dimensional devices with vertical stacks of multiple layers of semiconducting structures. For example, in NAND flash memory devices, lateral relative arrangement (CMOS near Array, or CnA) of memory cells (e.g., floating gate transistors) and peripheral transistors (e.g., CMOS circuitry used to support write/read operations with memory cells) has mostly given way to a vertical arrangement (CMOS under Array, or CuA) in which peripheral CMOS circuitry is disposed below an array of memory cells. In some instances, stacks of layers of memory cells can be manufactured on top of other stacks creating a structure in which precise alignment of various features within the layers is important for proper functioning of the manufactured devices. In one example of NAND flash memory device manufacturing, a stack of multiple alternating oxide (O) and nitride (N) layers (e.g., silicon oxide and silicon nitride layers, in one example) can be deposited on top of a silicon wafer. In another example of a three-dimensional (3D) Dynamic Random-Access Memory (DRAM) manufacturing, a stack of alternating Si₁₋ₓGeₓ (SiGe) alloy layers and silicon (e.g., epitaxial silicon) layers can be deposited on top of a silicon wafer. Vertically stacked features can include, e.g., logic circuitry stacked on memory circuitry or other logic circuitry, interposer circuitry (interconnects) placed between vertically stacked dies or chips, and/or the like. Such vertical stacking can be accomplished using various hybrid bonding techniques, including bonding a first wafer supporting a first set features (e.g., logic/memory/circuitry) to a second wafer (via the wafer-to-wafer bonding process) that supports a second set of features, aligning the second set of features with the first set of features, and then transferring the second set of features to the first wafer (while removing the second wafer).

In Backside Power Delivery Network (BS-PDN) manufacturing, a bonding (adhesion) layer can be placed over the first set of features of the first wafer and the first wafer can be bound (adhered) to the second wafer. The first wafer can subsequently be chemically thinned or mechanically grinded until some of the first set of features are exposed from the back side of the first wafer. An additional second set of features (e.g., circuitry, dies, and/or the like) can then be deposited (stacked) over the exposed first set of features with the second wafer playing the role of the substrate for the stacked features (including both the first and the second set of features). Subsequently, the stacked features and the first/second wafer can be cut into individual devices, e.g., dies or chips.

By delivering additional features to a wafer's backside, the BS-PDN techniques increase transistor density and free up space on the wafer's frontside. However, successful application of the BS-PDN technology involves a complex direct wafer-to-wafer bonding process, where a first wafer (a device wafer) is flipped and bonded to a second wafer (a carrier wafer), which is usually followed by annealing, grinding, and/or etching. Backside lithography patterning requires precise overlaying of features and is particularly sensitive to the presence of local stress caused by features (dies, and/or the like) formed on the front side of the device wafer.

Die/wafer deformation can lead to misalignment of features manufactured using the BS-PDN techniques and result in substandard or inoperable devices, including such defects as cracking of dies, delamination of dies, dies that fail to adhere to substrates, dies that display inconsistent electrical contacts, dies having mismatched circuitry, and/or the like. Correcting local die-level deformations is, therefore, important for ensuring high die/device quality. The local position-dependent character of the stresses makes stress mitigation particularly challenging with dies typically having a small size, e.g., a 5-30 mm, or less.

Aspects and embodiments of the present disclosure address these and other challenges of the modern semiconductor manufacturing technology by providing for systems and techniques that mitigate wafer stresses and deformations at a local (e.g., die-level or even smaller) scale for improvement of alignment of features manufactured in complex devices. In some embodiments, a set of features can be deposited on a first substrate and may cause local stresses in the substrate. For the sake of concreteness, such stresses can be referred to as die-level or die-scale stresses although the scale at which these stresses occur can range from multiple dies to a fraction of a die. The layer (stack) of features can be covered with a deformation-accommodation layer (DAL) that is used for local stress reduction, as disclosed below. In some embodiments, DAL can also function as a bonding layer to bind the first substrate to a second substrate. In other embodiments, the DAL can be a dedicated layer that is different from the bonding layer. A map of local stress variations σ(x, y) or deformation h(x, y) can be obtained and/or estimated for the first substrate. For example, the deformation can be measured using optical inspection or other suitable techniques. In some embodiments, the deformation and/or stresses can be estimated using simulations (e.g., finite difference method, and/or the like) performed for a known topology of the deposited features. A protective layer can be formed on the DAL with a pattern that correlates with the local stress variations σ(x, y) in the substrate. The protective layer and the underlying DAL can be exposed to one or more agents that modify elastic properties of the DAL. For example, the DAL can be exposed to an ion beam, a beam of photons, a plasma etch environment, and or the like. The mask protects certain regions of the DAL while exposing other—target—regions to the beam and/or etch environment. This causes removal of certain portions of the DAL. Subsequently, when the second substrate is pressed and adhered to the first substrate, the removed portions cause the second substrate to deform around the removed portions. As the back side of the first substrate undergoes thinning, the removal of the bulk of the first substrate (and the corresponding stresses) reduces the stresses in the second substrate and restores the second substrate to an undeformed (or weakly deformed) state. The sizes of the removed portions of the DAL can be selected, e.g., using various modeling techniques, to maximize reduction of stresses/deformation in the second substrate.

Additional stress-mitigation techniques can include subjecting one or more layers formed on the first and/or second substrate to an irradiation by a stress-modification beam. The stress-modification beam can include particles (e.g., ions, electrons), electromagnetic waves (e.g., UV light, visible light, infrared light, etc.), and/or a suitable combination thereof. The stress-modification beam can irradiate the DAL or a separate stress-compensation layer (SCL) that can be formed on the system after bonding and stress/deformation reduction facilitated by the DAL. In particular, the SCL can be formed to compensate for a global (e.g., positive or negative bow) isotropic deformation/stress of the substrate(s) with the type of the SCL (e.g., tensile or compressive) and the thickness of the SCL selected for maximum compensation of the isotropic deformation/stress. Subsequently, the SCL can be exposed to the particles of the stress-modification beam that can compensate for global anisotropic (e.g., saddle-shape, cylindrical, etc.) and/or residual deformation of the substrate structure by changing the bonding network of the SCL. For example, the stress-modification beam of low energy may interact with surface atoms of the SCL, e.g., removing some of the surface atoms, effectively implementing etching of surface regions of the SCL. The effectiveness of such etching may be controlled by a choice of ion species/radicals/ambient gasses. In another example, the stress-modification beam of high energy can deposit ions inside the SCL. Ions and/or photons of the beam can break of the bonding network (or crystal lattice) of the SCL forming vacancies therein, and can further cause annealing due to local heating, UV curing, and/or other effects. Substitution defects and/or vacancies created by the particles of the stress-modification beam modify (e.g., reduce) stress in the SCL and, through the SCL, in the wafer. The intensity and/or dose (the intensity integrated over time) of the stress-modification beam can vary with a location within the SCL and can be determined (e.g., simulated, modeled, etc.) in a way that maximally relieves the stress in the SCL and, further, in the wafer. This causes the combination of the substrate, the deposited layers/films, and the SCL to flatten and facilitates precise alignment of features that are patterned on the substrate, etched in one or more stacks of layers, and/or the like, and improves quality of the manufactured devices. The intensity/doses of irradiation can be determined based on measured deformation of the system (with layers/films/mask deposited thereon), e.g., using various optical measurement techniques. Multiple techniques can be used to determine optimal intensity and/or dose of the stress-modification beam, such as Monte Carlo simulations, influence function computations, and/or other techniques, as disclosed below. In some embodiments, the stress-modification beam can also be applied to the DAL, e.g., prior to bonding of the substrates.

Advantages of the disclosed embodiments include but are not limited to a significant reduction of the costs of deformation/stress correction of substrates and combinations of substrates in semiconductor manufacturing and a more accurate alignment of features manufactured on the substrates, including high aspect ratio features in vertically grown semiconductor devices.

A “wafer,” as used herein, refers to any substrate or material surface formed on a substrate upon which film processing is performed during a fabrication process. For example, a wafer surface on which processing can be performed includes any intrinsic (undoped) or doped materials such as silicon, silicon oxide, silicon nitride, strained silicon, silicon on insulator, silicon oxides with carbon, amorphous silicon, germanium, gallium arsenide, glass, sapphire, plastic, and any other materials such as metals, metal nitrides, metal alloys, and other conductive materials, depending on the application. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

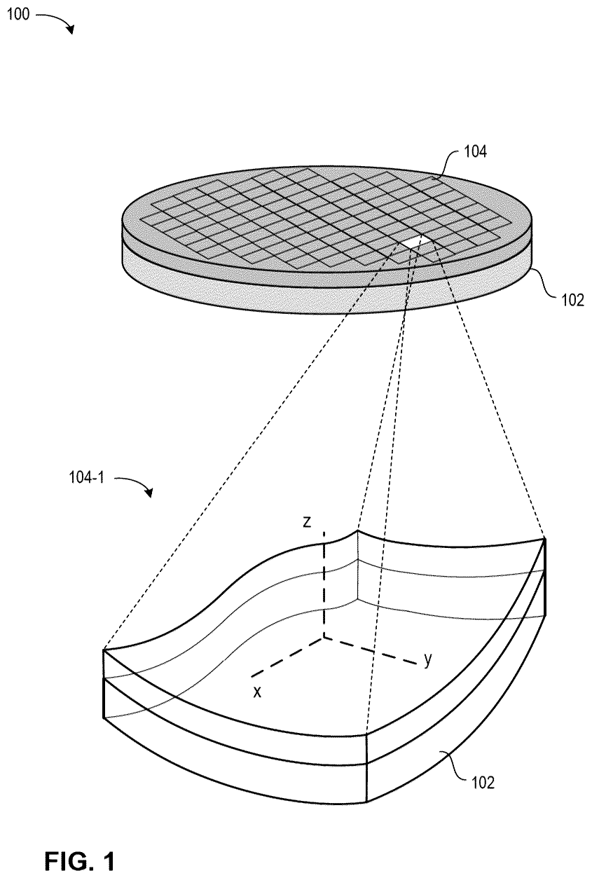

FIG. 1 illustrates schematically stresses in an example substrate structure 100 that can be mitigated using the techniques of the instant disclosure. Example substrate structure 100 includes a first substrate 102 and a stack 104 of features deposited (or otherwise formed) thereon. The stack 104 can include any devices (e.g., transistors, memory and/or logic) and/or additional circuitry (e.g., a wire interconnect). The exploded view in FIG. 1 further illustrates an example feature 104-1 of the stack 104 having a deformation (the degree of deformation may be exaggerated in FIG. 1).

In some embodiments, deformation of first substrate 102 (with the stack 104 of features deposited thereon) can be measured (e.g., using optical measurements techniques) and parameters for an optimal DAL (and/or) SCL can be selected, including DAL material, thickness, and/or the like. Additionally, an SCL can be formed on first substrate 102, e.g., prior to or after deposition of the DAL, or after first substrate 102 is bonded to a second wafer. Type and/or thickness of the SCL can be selected to reduce the global stress in the wafer structure.

Further stress mitigation can include applying an ion (electron, photon) beam to the DAL and/or SCL to modify (e.g., reduce) stress in the DAL/SCL to a desired level. Parameters of an ion (or other particles/waves) implantation map (a distribution of local doses of ion implants) n(x, y) and/or photon irradiation can be computed to reduce the local stress in the wafer σⱼₖ(x, y) to a degree that brings the shape of the wafer to a flat (or nearly flat) shape. A number of techniques can be used for determining an optimal ion implantation map.

The stress-modification beam can include matter particles (e.g., ions, electrons), electromagnetic waves (e.g., UV light, visible light, infrared light, etc.), and/or a suitable combination thereof. The stress-modification beam strikes the DAL and/or SCL and changes the bonding network of the DAL and/or SCL. For example, the stress-modification beam of low energy may interact with surface atoms of the DAL and/or SCL, e.g., removing some of the surface atoms, effectively implementing etching of surface regions of the DAL and/or SCL. The effectiveness of such etching can be controlled by a choice of ion species/radicals/ambient gasses. In another example, the stress-modification beam of high energy can deposit ions inside the DAL and/or SCL. Particles and/or photons of the beam can break bonds of the bonding network (or crystal lattice) of the DAL and/or SCL forming vacancies therein, and can further cause annealing due to local heating, UV curing, and/or other effects. Substitution defects and/or vacancies created by the particles of the stress-modification beam modify (e.g., reduce) stress in the DAL and/or SCL and, through the DAL and/or DAL and/or SCL, in the wafer. The intensity and/or dose (the intensity integrated over time) of the stress-modification beam can vary with a location within the SCL and can be determined (e.g., simulated, modeled, etc.) in a way that maximally relieves the stress in the DAL and/or SCL (and, further, in the wafer). This causes the combination of the wafer, the deposited features/films, and the DAL and/or SCL to flatten and facilitates precise alignment of features that are patterned on the wafer, etched in one or more stacks of layers, and/or the like, and improves quality of the manufactured devices. The intensity/doses of irradiation can be determined based on the measured deformation of the wafer. Multiple techniques can then be used to determine optimal intensity and/or dose of the stress-modification beam, such as Monte Carlo simulations, influence function computations, and/or other techniques, as disclosed below.

Stresses σⱼₖ(x, y) that can be mitigated using these techniques include, but are not limited to, stresses that occur in the first wafer globally, as a result of film deposition, global wafer thinning, polishing, cleaning, and/or the like. The mitigated stresses can further include stresses that occur in the wafers because of patterning of the wafers, e.g., deposition of features on the wafers, cutting of the wafers (with the stacked structure placed thereon), and/or the like.

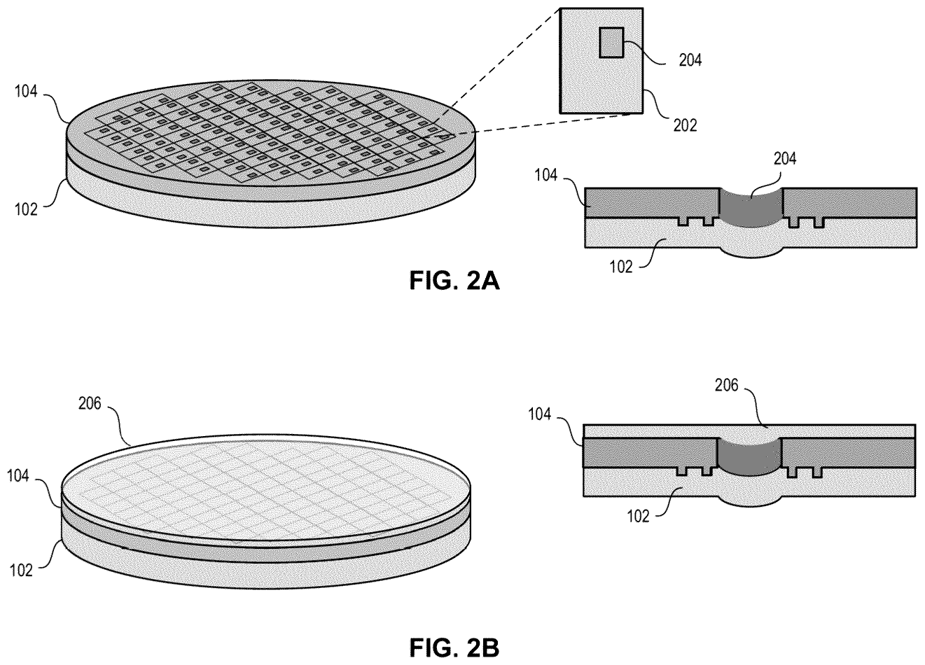

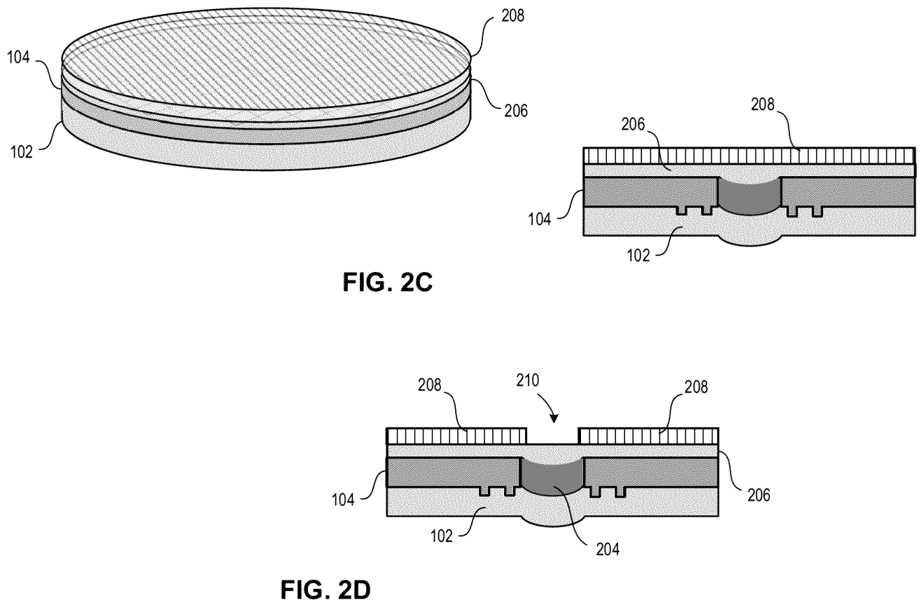

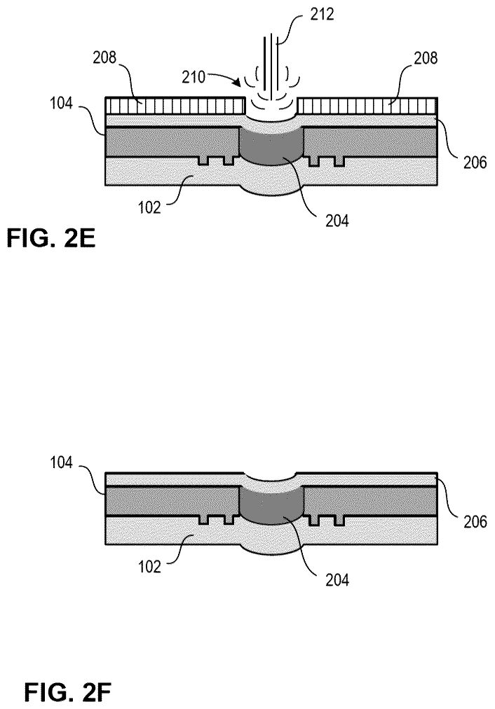

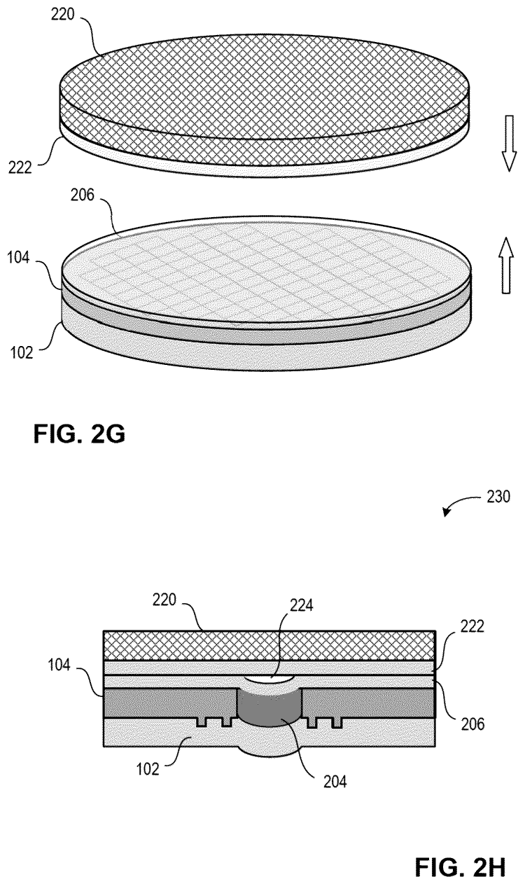

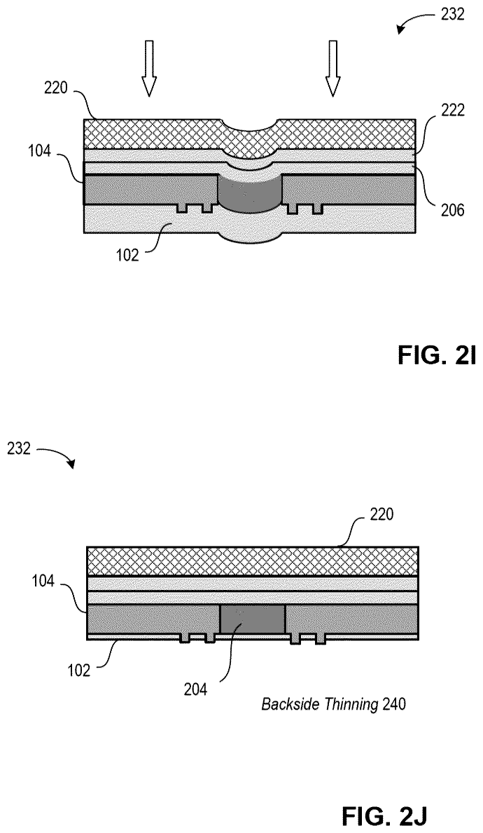

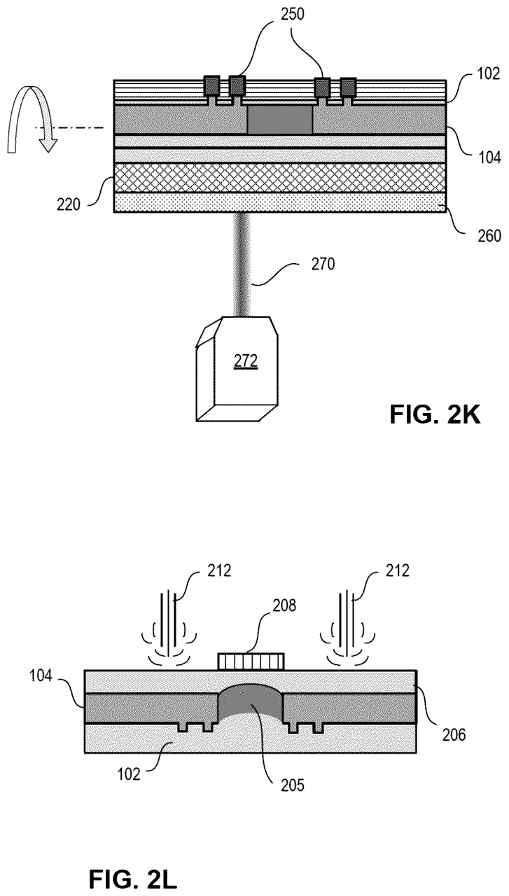

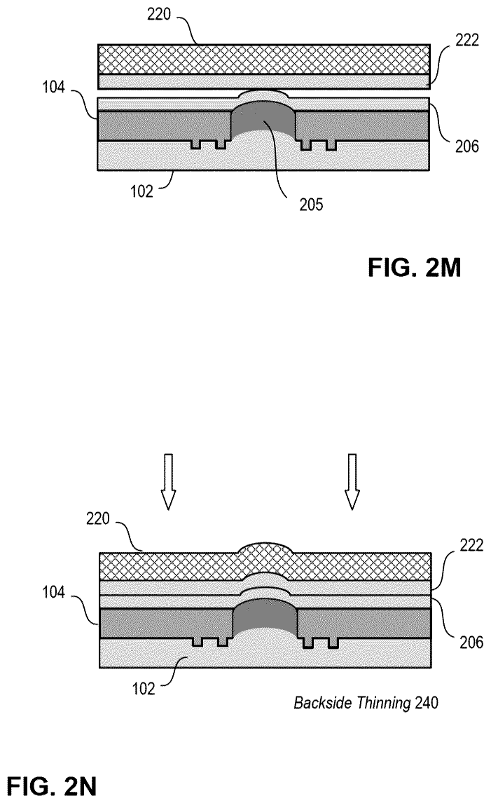

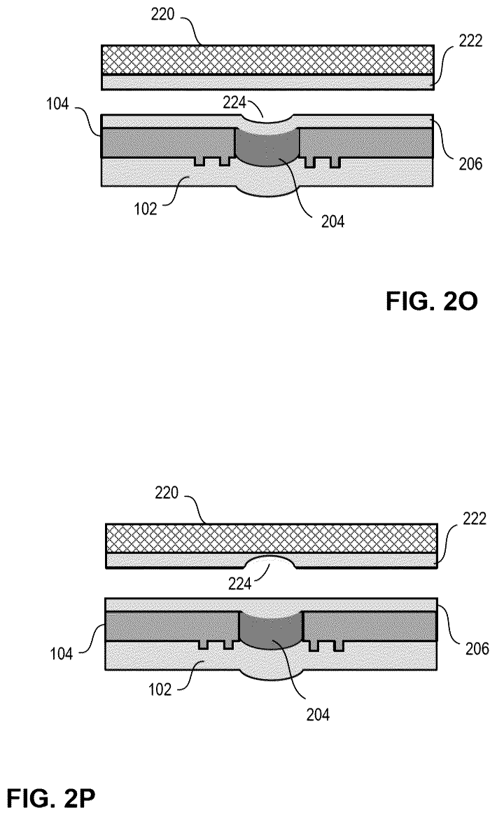

FIGS. 2A-2P illustrate mitigation of local stresses and deformations in complex multi-substrate manufacturing structures, according to at least one embodiment. FIG. 2A shows schematically a sample that includes first substrate 102 supporting a stack 104 of features. In some embodiments, first substrate 102 may have previously undergone any additional treatment, such as annealing. The left depiction in FIG. 2A (and, similarly, in FIG. 2B and FIG. 2C) illustrates the perspective view of the structures formed on first substrate 102 (and features deposited thereon); the right depiction is a cross-sectional view of a portion of the same structures. Stack 104 can include source lines of NAND devices, DRAM devices, flash memory devices, and/or the like, stacks of memory and/or logic transistor layers, interconnect circuitry, uniform (unpatterned) films, patterned films, die boundaries, chip boundaries, area boundaries, slits, channels, and/or any other applicable features. Stack 104 can be deposited (or otherwise formed) using atomic layer deposition techniques, photolithography techniques, etching techniques, chemical-mechanical polishing (CMP) techniques, and/or any other techniques. A blowout segment in FIG. 2A illustrates schematically an individual die-sized portion 202 having a local feature 204 causing a local deformation of first substrate 102.

As illustrated in FIG. 2B, stack 104 can be covered with a deformation-accommodation layer (DAL) 206. In some embodiments, DAL 206 can be a bonding (adhesion) layer to bind first substrate 102 (with various structures deposited thereon) to a second substrate. In other embodiments, DAL 206 can be a dedicated layer that is different from the bonding layer. DAL 206 can be deposited using chemical vapor deposition (CVD) techniques, physical deposition techniques, or other deposition techniques, growth techniques, spin-coating techniques, and/or the like. In some embodiments, DAL 206 can be made from silicon nitride Si₃N₄, silicon oxide SiO₂, silicon carbon-nitride SiCN, aluminum nitride AlN, and/or some other suitable material or a combination of such materials. In some embodiments, the level of stress in DAL 206 can be determined based on (global) deformation of first substrate 102 and various structures deposited thereon such that deposition of DAL 206 corrects parabolic bow warping of first substrate 102. The level of stress in DAL 206 can be controlled by controlling conditions in the processing chamber during deposition of DAL 206, including but not limited to concentration of argon and/or nitrogen atoms (or ions) in the environment of the processing chamber, voltage, temperature, and/or the like. In some instances, DAL 206 can have a tensile stress while, in other instances, DAL 206 can have a compressive stress. The type of SCL (tensile vs. compressive) can be determined by a (measured and/or inferred) sign of stress in first substrate 102 prior to deposition of DAL 206. In some embodiments, the magnitude of stress of DAL 206 can be set based on a magnitude of stress in first substrate 102, e.g., as can be inferred from one or more simulations.

In some embodiments, a stress-modification beam (not shown in FIG. 2B) can be applied to DAL 206 to deliver a position-dependent dose of ions and/or photons n(x, y), where x, y are in-plane coordinates within the wafer/SCL plane. The stress-modification beam can further reduce stresses in the structure shown in FIG. 2B, e.g., to mitigate anisotropic (e.g., cylindrical, saddle-shape, etc.) stresses.

As illustrated in FIG. 2C, a protective mask 208 can be placed over DAL 206 to facilitate subsequent patterning of DAL 206 as part of mitigation (in conjunction with other techniques disclosed below) of stresses caused by local features 204. As illustrated in FIG. 2C, protective mask 208 can be removed at a number of openings 210. Placement of openings 210 can correlate with local features 204 in stack 104. For example, as illustrated, a given opening 210 can be (but need not be) located near a corresponding local feature 204 such that the region of DAL 206 situated above the local feature 204 is unprotected by protective mask 208. In some embodiments, openings 210 can be placed between local features 204 such that the regions of DAL 206 above the local features 204 remain protected by the protective mask 208 whereas other areas are exposed.

In some embodiments, protective mask 208 can (or include) a photoresist layer. The photoresist can be shielded with a photomask having a target pattern that is to be transferred to the photoresist. The areas of the photoresist unprotected by the photomask can then be exposed to light, e.g., using UV light (including UVA, UVB, UVC, far UV, and extreme UV light), visible light, infrared light, and/or the like. The photoresist can then be developed by removing the photomask and the exposed (or unexposed, depending on a specific type of photoresist) areas of the photoresist to create openings 210. The remaining, after development, portions of the photomask can be removed by ashing or similar techniques. In some embodiments, protective mask 208 (with openings 210 therein) can be formed using contact printing (contact lithography) techniques, in which the photomask is pressed against the photoresist (protective mask 208).

As illustrated in FIG. 2E, DAL 206 can then be exposed, through the opening(s) 210 in the protective mask 208, to one or more suitable agents 212 to remove a portion of DAL 206, e.g., to create a profile in the protective mask 208 that matches or correlates to a profile of deformation caused by local feature(s) 204. In some embodiments, agent(s) 212 can include reactive-ion etching agents, etch radicals agents, plasma ashing agents (e.g., using oxygen, fluorine, a combination of nitrogen and hydrogen, and/or the like), wet chemical etching/cleaning, and/or the like. In some embodiments, agent(s) 212 can include a beam of ions, a beam of photons, and/or the like. For example, a beam of photons can ablate one or more target portions of DAL 206. In some embodiments, multiple agents 212 can be deployed. For example, during a first stage, a beam of ions and/or photons can be used to modify (e.g., soften) the bonding network of DAL 206 within certain target areas. During the second stage, the target areas of DAL 206 can be removed, e.g., using one or more etch techniques.

As illustrated in FIG. 2F, protective mask 208 can be removed after treatment of DAL 206 with agents 212. For example, protective mask 208 can be dissolved, etched or ashed away, grinded, and/or otherwise removed using any suitable techniques. Although, in some embodiments, the removal of protective mask 208 can be subsequent to the removal of a target portion of DAL 206 (as illustrated with FIGS. 2E-2F), in other embodiments, the removal of protective mask 208 and the removal of the target portion of DAL 206 can be performed together. For example, after the target portion of DAL 206 is treated (softened) with an ion beam or a photon beam, the target portion of DAL 206 can be dissolved together with protective mask 208, while the untreated portions of DAL 206, shielded by protective mask 208, can be resistant to the dissolution.

As illustrated in FIG. 2G, first substrate 102 (with the stack 104 of features and DAL 206) can be bonded with a second substrate 220. Second substrate 220 can be a glass wafer (e.g., SiO₂ wafer), a silicon wafer, a corundum wafer, and/or any other suitable type of substrate. Bonding of second substrate 220 to first substrate 102 can be facilitated by a suitable adhesion layer 222, which can be similar to or different from DAL 206, in physical and/or chemical composition. In some embodiments, instead of using adhesion layer 222, a fusion bonding can be performed to bond second substrate 220 directly to DAL 206 of the first substrate 102.

FIG. 2H depicts a pre-bonded structure 230 in which second substrate 220 (with the adhesion layer 222) is placed on top of first substrate 102 (with the stack 104, DAL 206, and local feature 204), and adhesion layer 222 (and can further enclose any additional layers, films, patterns, and components). As adhesion layer 222 makes contact with DAL 206, a cavity 224 can be present therebetween, location and dimensions of the cavity 224 determined by the dimensions of opening 210 and type(s) and characteristics of agents 212 (e.g., concentration, mass, energy, exposure time, and/or the like) that are used to form the cavity in DAL 206 (with reference to FIG. 2E).

As illustrated in FIG. 2I, pressing second substrate 220 into first substrate 102 causes bonding of adhesion layer 222 to DAL 206. As a result, second substrate 220 can experience a deformation caused by filling the cavity in DAL (e.g., cavity 224 in FIG. 2G) resulting in a deformed bonded structure 232 in which both wafers are deformed. Although for simplicity, deformation of first substrate 102 in the bonded structure 232 is shown to be the same as in pre-bonded structure 230 in FIG. 2H, under practical conditions, bonding of the (undeformed) second substrate 220 can cause reduction of deformation of first substrate 102 compared to its deformation in the pre-bonded structure 230. The degree of such reduction can depend on relative elastic properties and dimensions of the two wafers. For example, in the case of the two substrates having the same dimensions (e.g., thickness) and elastic moduli, the deformation of first substrate 102 can be reduced by approximately two times.

As illustrated in FIG. 2J, the bonded structure 232 can undergo backside thinning 240, e.g., until the stack 104 (or a portion of the stack) is exposed through the backside of the first substrate 102. Backside thinning 240 can include grinding, chemical mechanical polishing (CMP), wet etching, dry etching, polishing, and/or the like. As backside thinning 240 removes material of the first substrate 102, stresses in the first substrate 102 decrease and the second substrate 220 goes to an undeformed (or weakly deformed) state.

As illustrated in FIG. 2K, additional features 250 can be formed on the back side of the first wafer (in FIG. 2K, the bonded structure 232 is turned over), the additional features 250 making contact with the exposed features of stack 104. These additional features can include memory and/or logic transistors, interconnect circuitry, other conducting or semiconducting devices, and/or the like, or some combination thereof.

As further illustrated in FIG. 2K, an SCL 260 can be formed on the back side of second substrate 220 for further elimination of stresses at scales that are large compared with individual features of the stack 104. SCL 260 can be deposited using chemical vapor deposition (CVD) techniques, physical deposition techniques, or other deposition techniques, growth techniques, spin-coating techniques, and/or the like, in some embodiments. In some embodiments, SCL 260 can be made from silicon nitride Si₃N₄ or some other material whose stress can be efficiently controlled during deposition of SCL 260. The level of stress in SCL 260 can be set by controlling conditions in the processing chamber during deposition of SCL 260, including but not limited to concentration of argon and/or nitrogen atoms (ions) in the environment of the processing chamber, voltage, temperature, and/or the like. In some instances, SCL 260 can have a tensile stress while, in other instances, SCL 260 can have a compressive stress. The type of SCL (tensile vs. compressive) can be determined by a (measured and/or inferred) sign of stress in first substrate 102 prior to the SCL deposition. Similarly, the magnitude of stress of SCL 260 can be determined (measured and/or inferred) based on a magnitude of stress in the combined sample made of the first wafer, the second wafer, and various films and features deposited thereon.

As further illustrated in FIG. 2K, a stress-modification beam 270 can be applied to SCL 260 to deliver a position-dependent dose of particles and/or photons n(x, y), where x, y are in-plane coordinates within the wafer/SCL plane. Stress-modification beam 270 can be generated by a suitable collimating and focusing column 272. While deposition of SCL 260 reduces global parabolic (bow-like) deformation of the sample, application of stress-modification beam 270 can reduce the stress in the sample to decrease further, resulting in the flattening of the sample and a reduction of any remaining deformation, e.g., cylindrical deformation, saddle-shape deformations, and/or any other additional (residual) deformation.

While FIGS. 2A-2J illustrate mitigation of stresses associated with example local feature 204 that causes downward (towards the back side of the first substrate 102) deformation, FIGS. 2L-2N illustrate similar mitigation of stresses associated with an example local feature 205 that causes upward (towards the front side of the first substrate 102) deformation. In one embodiment, patterning of the protective mask 208 can be inverted. For example, as illustrated in FIG. 2L, protective mask 208 can protect the region above local feature 205 while exposing other regions of DAL 206 to agents 212. Subsequent removal of the exposed regions leads to the geometry of the sample, as shown in FIG. 2M, when the second substrate 220 is being bonded to the first substrate 102, with a hump (rather than a trench) protruding towards the second substrate 220. As illustrated in FIG. 2N, pressing second substrate 220 into first substrate 102 causes the second substrate 220 to experience deformation that is opposite to the deformation illustrated in FIG. 2I for local feature 204. As the sample undergoes backside thinning 240 that removes material of the first substrate 102, stresses in the first substrate 102 decrease and the second substrate 220 returns to the undeformed (or weakly deformed) state illustrated in FIG. 2J.

FIG. 20 and FIG. 2P illustrates different placement of cavities 224. FIG. 20 illustrates placement of cavity 224 within DAL 206 supported by first substrate 102. FIG. 2P illustrates placement of cavity 224 within adhesion layer 222 supported by second substrate 220.

In some embodiments, prior to irradiating SCL 260 (and/or DAL 206) with stress-modification beam 270 (with reference to FIG. 2K), the amount of stress a sample, e.g., in first substrate 102 (with films and mask deposited thereon) and/or composite structure made of first substrate 102 and second substrate 220, can be determined by measuring a profile h(\vec{r}) of the sample. The profile h(\vec{r}) can refer to the vertical coordinate of the bottom surface of the sample. In some instances, stress in the sample can be uniform and isotropic, σₓₓ≈σ_{yy}. In some instances, stress in the sample can be anisotropic, σₓₓ≠σ_{yy}. Certain feature patterns can result in stresses that are tensile along one direction, e.g., σₓₓ>0, and compressive along a perpendicular direction, σ_{yy}<0, resulting in saddle-shaped wafers. Such saddle-shaped features can arise, for example, in stacks of materials with directional patterning, e.g., patterning of wordlines in NAND devices.

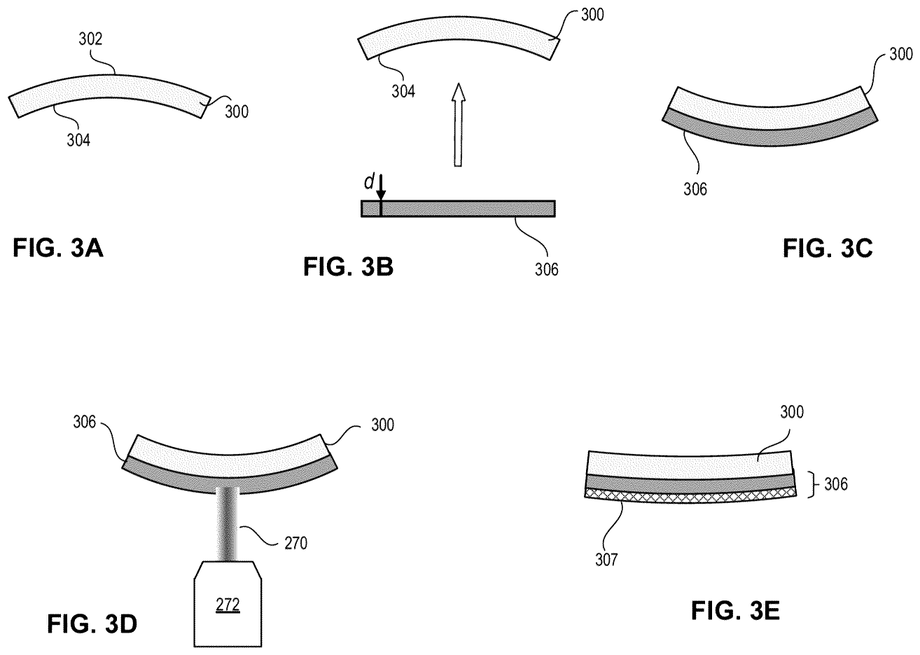

In some embodiments, a vertical profile of the sample deformation z=h(\vec{r}) can be measured using optical metrology (e.g., optical interferometry) techniques. In some embodiments, wafer deformation z=h(\vec{r}) can be measured after a stack 104 of layers/films is deposited on the sample. The wafer profile h(\vec{r}) can then be represented via a number of parameters that qualitatively and quantitatively characterize geometry of the wafer deformation, e.g., a set of Zernike (or a similar set of) polynomials, h(\vec{r})=ΣⱼAⱼZⱼ(\vec{r}). Consecutive coefficients A₁, A₂, A₃, A₄ . . . represent weights of specific geometric features (elemental deformations) of first substrate 102 described by the corresponding Zernike polynomials Zⱼ(\vec{r}). In some embodiments, a material of the SCL (and/or DAL) can be selected based on the sign of a paraboloid bow coefficient A₄. In some embodiments, selection of a thickness d of the SCL (and/or DAL) can be made based on a value of the paraboloid bow coefficient A₄. As illustrated in FIGS. 3A-3E, thickness d of the SCL (and/or DAL) can be selected to overcorrect the wafer deformation to some degree. The overcorrection can be chosen in conjunction with a type of stress-modification beam (e.g., ion implants, photons, electrons, etc.), a type of implant species, energy, and dose to ensure maximum effect from the stress mitigation. Stress in the combined structure of the wafer, films, and the SCL (and/or DAL) can then be modified by a stress-modification beam that strikes the SCL (and/or DAL) and changes its crystal (or amorphous) structure. Substitution defects and/or vacancies created by the stress-modification beam reduce stress in the SCL (and/or DAL) and can reduce the degree of stress overcorrection caused by the SCL (and/or DAL) deposition. This causes the wafer to flatten.

FIGS. 3A-3E illustrate schematically a process of correcting a sample deformation using a stress-modification beam applied to the back side of a sample, according to at least one embodiment. FIG. 3A depicts a sample 300 (e.g., a substrate with films/features deposited thereon or a composite structure that include multiple substrates) having a deformation, which can include a paraboloid bow deformation (with positive coefficient A₄>0, as illustrated) and can further include other deformations, including saddle deformation, residual deformation, etc. The sample's front side 302 can include any number of features, e.g., deposition and/or etching patterns, a stack of layers/films, and/or any other structures. The sample's front side 302 can include any number of features, deposition and/or etching patterns, a stack of layers/films, and/or any other structures. FIG. 3B illustrates deposition of SCL 306 on the back side 304 of sample 300. SCL 306 can be (or include) a silicon nitride layer or some other type of material. In some embodiments, SCL 306 can include layers of multiple materials. In some embodiments, a material of SCL 306 can be selected in view of the sign of coefficient A₄. For example, for a negative bow, A₄<0, SCL 306 can be selected to have a compressive stress (as illustrated in FIGS. 3B-3E). Conversely, for a positive bow, A₄>0, SCL 306 can be selected to have a tensile stress. SCL 306 can be deposited using any suitable deposition techniques including physical vapor deposition (e.g., sputtering), chemical vapor deposition (e.g., plasma-assisted deposition), epitaxy, exfoliation, and/or the like. SCL 306 can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). In some embodiments, thickness d of SCL 306 can be selected to overcorrect the wafer deformation to some degree, e.g., as illustrated in FIG. 3C where a negative paraboloid is overcorrected to a positive paraboloid bow. The thickness-dependent paraboloid bow correction A_{corr}(d) changes wafer deformation from h(r, ϕ) to h_{corr}(r, ϕ):

$${h}_{corr} ( r , ϕ ) = h ( r , ϕ ) + {A}_{corr} ( d ) \cdot {Z}_{4} ( r , ϕ ) .$$

The degree of overcorrection can be chosen in conjunction with a type and parameters (e.g., energy, dose, etc.) of a specific stress-modification beam 270 to be used on SCL 306. The overcorrection can make the combined structure of first substrate 102 and SCL 306 susceptible to further control of stress (and thus control of deformation of the wafer h_{corr}(r, ϕ)). As illustrated in FIG. 2D, collimating and focusing column 272 can generate a stress-modification beam 270 that strikes SCL 306 and changes its elastic properties, e.g., by creating vacancies, breaking crystal bonds, depositing ions, and/or via any other applicable mechanisms. Stress-modification beam 270 can carry photons, electrons, silicon ions, phosphorus ions, argon ions, neon ions, xenon ions, krypton ions, and/or the like. In some embodiments, the energy and type of ions in stress-modification beam 270 can be selected to limit the implanted ions to the volume of SCL 306 without allowing the ions to reach sample 300 (and/or any layers/films deposited on sample 300). Ions that lodge in SCL 306 create substitution defects therein. Additionally, the ions leave a trail of vacancy defects along paths of propagation in SCL 306. The substitution defects and/or vacancies mitigate (e.g., reduce) stress in SCL 306 and can reduce the degree of stress overcorrection caused by the SCL deposition. This causes the combination of sample 300 and SCL 306 to flatten.

In some embodiments, the number of ions ΔNᵢ deposited per small area ΔA=ΔxΔy (or the total amount of photon energy applied to this area) of sample 300 can be determined using simulations (performed as described in more detail below) based on the local value of the corrected deformation h_{corr}(r, ϕ), which may include a saddle deformation, a residual deformation, and the part of the paraboloid bow deformation

A_{corr}(d)+A₄ that has been overcorrected by the deposition of stress-compensation layer 306. The target local density n(x, y)=ΔNᵢ/ΔxΔy of the ions can be delivered by controlling the scanning velocity v of stress-modification beam 270. In some embodiments, stress-modification beam 270 has a profile that can be approximated with a Gaussian function, e.g., the ion flux j(ρ)=j₀exp (−x²/a²−y²/b²), where x and y are Cartesian coordinates, j₀ is the maximum ion flux at the center of the beam, and a and b is are characteristic spreads of the beam along the x-axis and y-axis, respectively. Correspondingly, a point that is located at distance y from the path of the center of the beam receives an ion dose that includes the following number of ions:

$$\frac{Δ {N}_{i}}{Δ x Δ y} = \frac{{j}_{0}}{v} {\int }_{- ∞}^{∞} dx {e}^{- {x}^{2} / {a}^{2} - {y}^{2} / {b}^{2}} = \frac{{j}_{0} \sqrt{π}}{va} {e}^{- {y}^{2} / {b}^{2}} .$$

Correspondingly, by reducing the scanning velocity v, the number of ions received by various regions of SCL 306 can be increased, and vice versa. Additionally, stress-modification beam 270 can perform multiple scans with different offsets y so that various points of SCL 306 receive multiple doses of ions with different factors e^{-y}^{²}^{/b}^{²} that can average to a target dose. For example, after n passes of stress-modification beam 270, each made with a respective velocity vₖ at a different distance yₖ from the center of the beam to the area ΔxΔy, the total dose of ions (or amount of electromagnetic radiation) received by this area will be

$$n ( {x}_{,} y ) = \frac{Δ {N}_{i}}{Δ x Δ y} {\vert}_{total} = {j}_{0} \sqrt{π} {\sum }_{k = 1}^{n} \frac{{e}^{- {y}_{k}^{2} / {b}^{2}}}{{av}_{k}} .$$

As illustrated in FIG. 3E, a stress-modulated portion 307 of SCL 306 results in a significant mitigation of deformation of sample 300, including saddle and residual deformations.

In some embodiments, the intensity and/or total amount of irradiation per various areas of sample 300 can be determined using simulations, e.g., Monte Carlo simulations. The Monte Carlo simulations can be performed for a film made of the actual material used in SCL deposition and having a specific thickness d. An initial Monte Carlo simulation can be performed for specific baseline (default) conditions of the particle irradiation (e.g., default settings of an ion implantation apparatus). The baseline conditions can include a default type of particles, a default energy of the particles, a default dose of particles to be applied to SCL 306 (e.g., a default velocity of scanning and a default scanning pattern), and the like. The baseline conditions can subsequently be modified (e.g., optimized) using the Monte Carlo simulations. The Monte Carlo simulations can use calibration data collected (measured) for actual particle irradiation performed for various ion/photon/electron energies, types of ions, types and materials of masks/layers, angles of particle incidence on the films, and/or the like.

In some embodiments, the implantation map n(\vec{r}) can be computed using an influence function G(\vec{r}; \vec{r}′) that characterizes a response (e.g., deformation) at a point \vec{r} of the wafer as caused by a point-like force applied at another point \vec{r}′ of sample 300. In some embodiments, the influence function G(\vec{r}; \vec{r}′), also known as the Green's function, can be determined from computational simulations or from analytical calculations. In some embodiments, the influence function can be determined from one or more experiments, which can include performing ion implantation into a film deposited on a reference wafer.

In some embodiments, wafer deformation h(\vec{r})=h_{quad}(\vec{r})+hᵣₑₛ(\vec{r}) can be represented (decomposed) as a combination of a quadratic h_{quad}(\vec{r}) and residual (non-quadratic) hᵣₑₛ(\vec{r}) contributions. The quadratic deformation can include a parabolic (paraboloid) part hₚₐᵣ(\vec{r}), which has the complete axial symmetry, and a saddle part h_{saddle}(\vec{r}). The thickness d of SCL 306 can be computed (or empirically determined) in such a way that the mask is to apply a desired target stress to sample 300. To eliminate a non-uniform saddle deformation, SCL 306 can be of such thickness/material that turns the saddle deformation into a cylindrical deformation having a definite sign throughout the area of sample 300. The uniform-sign cylindrical deformation (as well as a residual higher-order non-quadratic deformation) can then be mitigated with irradiation by stress-modification beam 270. In some embodiments, a cylindrical decomposition is not unique and can be either positive (upward-facing cylindrical deformation) or negative (downward-facing cylindrical deformation). Both decompositions can be analyzed and a decomposition that enables a more effective stress mitigation can be selected. For example, a decomposition that is characterized by a smaller parabolic bow deformation can be selected. The parabolic bow deformation can be mitigated using a choice of SCL 306 (e.g., type and thickness) while the remaining cylindrical deformation (and the higher-order residual deformation) can be addressed by appropriately selected ion or photon irradiation doses n(\vec{r}).

In some embodiments, mitigation of a cylindrical deformation or a saddle deformation can include identifying principal axes (directions) of the cylinder/saddle and a magnitude of the cylindric/saddle deformation and directing stress-modification beam 270 into appropriately selected edge regions of SCL 306. For example, individual edge regions to which the beam 270 is directed can have a width that is at or below 30% of a diameter of sample 300. Residual higher-order (ripple) deformations can then be mitigated with further irradiation into the area of SCL 306.

Some of these techniques will now be described in more detail. In one embodiment, a vertical profile of wafer deformation z=h(\vec{r}) can be measured using optical metrology techniques. For example, an interferogram of the profile h(\vec{r}) can be obtained using optical interferometry measurements. The wafer profile h(\vec{r}) can then be represented via a number of parameters that qualitatively and quantitatively characterize geometry of the wafer deformation. In some embodiments, a set of Zernike (or a similar set of) polynomials may be used to represent the wafer profile,

$$h ( \vec{r} ) = {\sum }_{j} {A}_{j} {Z}_{j} ( \vec{r} ) ,$$

where the planar radius-vector \vec{r}=(r, ϕ) may be represented as the radial coordinate r and the polar angle o within the (average) plane of the wafer. Consecutive coefficients A₁, A₂, A₃, A₄ . . . represent weights of specific geometric features (elemental deformations) of sample 300 described by the corresponding Zernike polynomials Z₁(r, ϕ), Z₂(r, ϕ), Z₃(r, ϕ), Z₄(r, ϕ) . . . (Herein, the Noll indexing scheme for the Zernike polynomials is being referenced.) The first three coefficients are of less interest as they describe a uniform shift of first substrate 102 (coefficient A₁, associated with the Z₁(r, ϕ)=1 polynomial), a deformation-free x-tilt that amounts to a rotation around the y-axis (coefficient A₂, associated with the Z₂(r, ϕ)=2r cos ϕ polynomial), and a deformation-free x-tilt that amounts to a rotation around the x-axis (coefficient A₃, associated with the Z₃(r, ϕ)=2r sin ϕ polynomial) that can be eliminated by a realignment of the coordinate axes. The fourth coefficient A₄ is associated with Z₄(r, ϕ)=\sqrt{3}(2r²−1) and characterizes an isotropic paraboloid deformation (“bow”). The fifth A₅ and the sixth A₆ coefficients are associated with Z₅(r, ϕ)=\sqrt{6}r² sin 2ϕ and Z₆(r, ϕ)=\sqrt{6}r² cos 2ϕ polynomials, respectively, and characterize a saddle-type deformation. The A₅ coefficient characterizes a saddle shape that curves up (A₅>0) or down (A₅<0) along the diagonal y=x and curves down (A₅>0) or up (A₅<0) along the diagonal y=−x. The A₆ coefficient characterizes a saddle shape that curves up (A₆>0) or down (A₆<0) along the x-axis and curves down (A₆>0) or up (A₆<0) along the y-axis. The higher coefficients A₇, A₈, etc., characterize progressively faster variations of the wafer deformation h(r, ϕ) along the radial direction, along the azimuthal direction, or both and collectively represent a residual deformation,

$${h}_{res} ( r , ϕ ) = h ( r , ϕ ) - {\sum }_{j = 4}^{6} {A}_{j} {Z}_{j} ( r , ϕ ) .$$

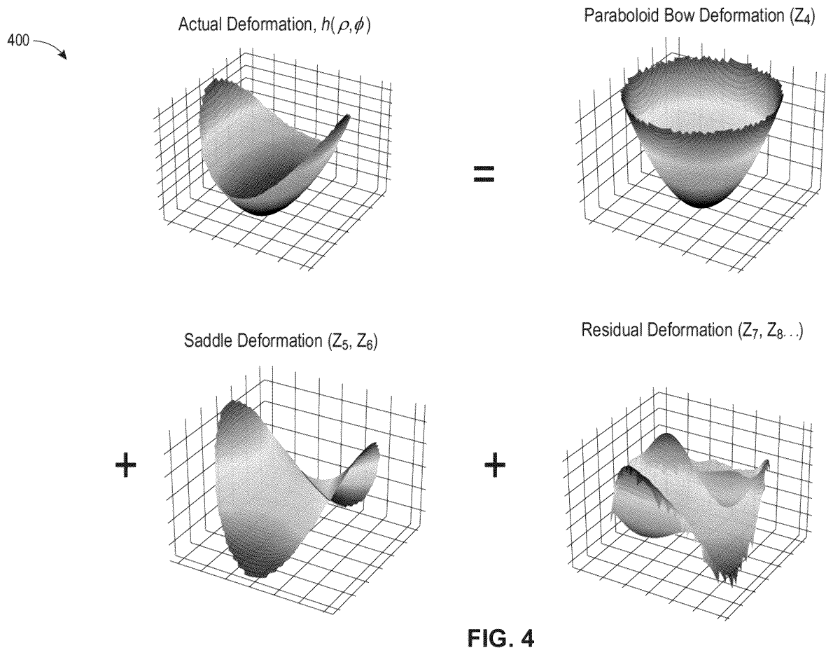

FIG. 4 illustrates an example Zernike polynomial decomposition 400 of one actual deformation h(r, ϕ) (top left) of a wafer (e.g., first substrate 102), in arbitrary units, into a paraboloid bow deformation A₄Z₄(r, ϕ) (top right), a saddle deformation A₅Z₅(r, ϕ)+A₆Z₆(r, ϕ) (bottom left), and a residual deformation, hᵣₑₛ(r, ϕ) (bottom right), according to at least one embodiment.

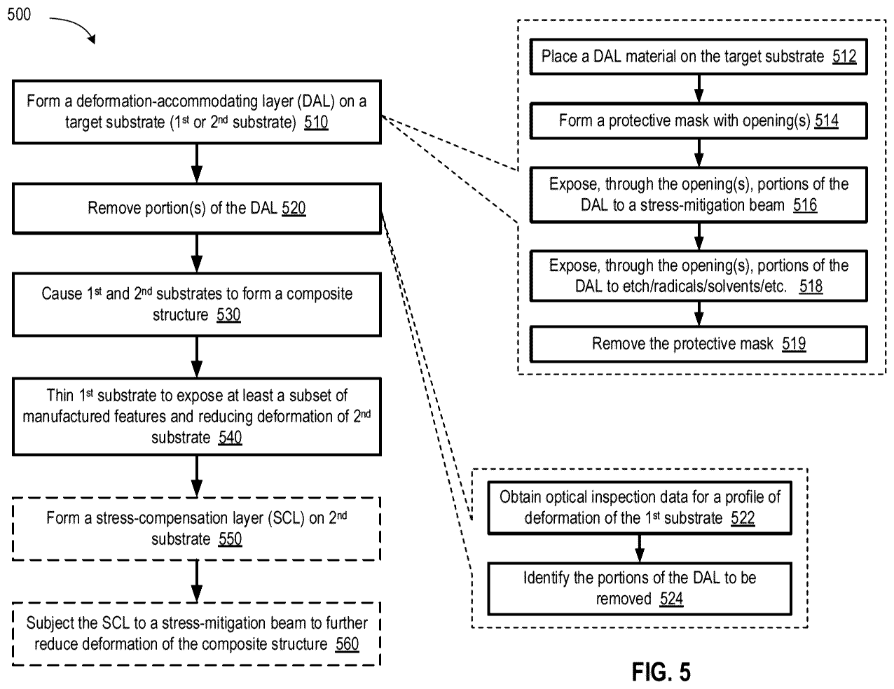

FIG. 5 is a flowchart illustrating an example method 500 of mitigation of local stresses and deformations in complex multi-substrate manufacturing structures, in accordance with at least one embodiment. Method 500 can be performed using a semiconductor manufacturing system that includes one or more processing chambers, e.g., deposition chamber(s), plasma chamber(s), etching chamber(s), polishing chamber(s), film removal chamber(s), beam irradiation chamber(s), optical inspection chamber(s), and/or the like. The processing chambers can be connected to one or more transfer chambers, which can be equipped with robot(s) to handle substrates, e.g., moving substrates into and out of processing chambers. The transfer chamber can further be connected to a load-lock chamber (Front-End Interface) that can be coupled to one or more Front Opening Unified Pod carriers that hold bare substrates, processed substrates, partially processed substrates, and/or the like. Operations performed by the semiconductor manufacturing system, including any, some or all operations of method 500, can be caused by a suitable processing device having a processing logic and memory to store instructions causing performance of operations of the method.

Method 500 can include preparing a first substrate (e.g., first substrate 102 in FIG. 2A), including but not limited to obtaining a bare substrate, preprocessing the bare substrate, e.g., polishing the substrate, removing stains and/or residue from the substrate, and/or the like, and/or performing any number of similar operations. Method 500 can further include depositing one or more films/layers, and/or other features (e.g., stack 104 in FIG. 2A) on the first substrate, e.g., one or more transistors, a layer of conducting features, e.g., source lines to be used as part of memory cell (transistor) interconnect circuitry. The features can further include multiple alternating nitride and oxide layers that are to be used as hosts of memory cells and separations between memory cells. In some embodiments, the features can include alternating silicon and silicon-germanium alloy layers.

At block 510, method 500 can include forming a deformation-accommodating layer (DAL) on a target substrate (e.g., DAL 206 in FIG. 2B). The target substrate can be the first substrate supporting one or more manufactured features or a second substrate. In some embodiments, the DAL can be formed using contact photolithography, proximity photolithography, projection photolithography, imprint lithography, or digital lithography.

In some embodiments, forming the DAL on the target substrate can include operations illustrated in the top callout portion of FIG. 5. More specifically, method 500 can include, at block 512, placing a DAL material on the target substrate. At block 514, method 500 can include forming a protective mask on the DAL material (e.g., protective mask 208 in FIG. 2D). In some embodiments, the protective mask can include a pattern of openings correlated with a pattern of deformation of the first substrate. The pattern of deformation can be caused by the one or more manufactured features. In some embodiments, at block 516, method 500 can include exposing, through the one or more openings of the protective mask, the one or more portions of the DAL to a beam of ions, a beam of photons, and/or a beam of electrons. In some embodiments, at block 518, method 500 can include exposing, through the one or more openings, the one or more portions of the DAL to an etch environment, an ashing environment, an environment containing one or more radicals, an environment one or more solvents, and/or the like. At block 519 method 500 can include removing, prior to causing the first substrate and the second substrate to form the composite structure, the protective mask.

At block 520, method 500 can include removing one or more portions of the DAL (e.g., as illustrated in FIG. 2E and FIG. 2F). In some embodiments, removing the one or more portions of the DAL creates a profile of the DAL that includes one or more elevated portions of a surface of the DAL (e.g., as illustrated in FIG. 2M and FIG. 2F), or one or more depressed portions of the surface of the DAL (e.g., as illustrated in FIG. 2H and FIG. 2I).

In some embodiments, removing the one or more portions of the DAL can include one or more operations illustrated with the bottom callout portion of FIG. 5. More specifically, at block 522, method 500 can include obtaining optical inspection data characterizing a profile of deformation of the first substrate. At block 524, method 500 can include identifying, using the optical inspection data, the one or more portions of the DAL to be removed.

At block 530, method 500 can include causing the first substrate and the second substrate to form a composite structure (e.g., as illustrated in FIG. 2H and FIG. 2I). In some embodiments, the DAL can serve as a bonding layer that includes an adhesion material facilitating formation of the composite structure from the first substrate and the second substrate. For example, the DAL can include a silicon oxide, a silicon nitride, a silicon-carbon nitride, an aluminum nitride, and/or the like.

At block 540, method 500 can include thinning the first substrate to expose at least a subset of the one or more manufactured features (e.g., as illustrated in FIG. 2J). The removal of the one or more portions of the DAL causes, responsive to the thinning, a deformation of the composite structure to be reduced. In some embodiments, the thinning of the first substrate can be performed using grinding, chemical-mechanical polishing, etching, exposure to a hydrofluoric acid, and/or any combination thereof.

In some embodiments, method 500 can include, at block 550, forming a stress-compensation layer (SCL) on the second substrate and, at block 560, subjecting the SCL to a stress-modification beam to further reduce the deformation of the composite structure (e.g., as illustrated in FIG. 2K).

Various additional operations are within the scope of method 500. For example, operations of block 522 and/or block 550 can include measuring the shape of the wafer, e.g., a displacement of a surface (e.g., the top surface) of a wafer as a function of some in-plane coordinates, e.g., polar coordinates z=h(r, ϕ), Cartesian coordinates, z=h(x, y), or any other suitable coordinates. Method 500 can further include decomposition of the determined shape over a suitable set of polynomials, e.g., Zernike polynomials, and obtaining a set of polynomial expansion coefficients, {Aⱼ}=(A₁, A₂, A₃), A₄, A₅, A₆, A₇, . . . , each coefficient in the set characterizing a degree of presence of a particular elemental geometric shape in the wafer's deformation.

In some embodiments, method 500 can include selecting a type of SCL to be used with the composite structure. For example, SCL made based on the coefficient that determines a degree of parabolicity of the deformation, e.g., coefficient A₄, of the composite structure. If the wafer is curved downwards (towards the back side of the composite structure), a tensile SCL can be selected. If the composite structure is curved upward (towards the front side of the wafer), a compressive SCL can be selected. Operations of method 500 can also include determining a type of a material for the SCL to be deposited and a thickness d of the SCL. In some embodiments, this determination can be made based on multiple expansion coefficients (more than just the paraboloid bow coefficient A₄) from the set {Aⱼ} or the full profile h(r, ϕ). In one specific non-limiting example, the thickness d can be determined as follows. First, a target paraboloid deformation Ã₄ can be determined that is sufficient to overcompensate for the measured wafer deformation, e.g., for h(r, ϕ)<0, the following condition can be satisfied:

$${\tilde{A}}_{4} {Z}_{4} ( ρ , ϕ ) + h ( r , ϕ ) ≡ ( {\tilde{A}}_{4} + {A}_{4} ) {Z}_{4} ( ρ , ϕ ) + {A}_{5} {Z}_{5} ( ρ , ϕ ) + {A}_{5} {Z}_{6} ( ρ , ϕ ) + … > 0.$$

In other words, the target paraboloid deformation Ã₄ can be chosen sufficiently large to compensate for the paraboloid deformation (A₄), saddle deformation (A₅ and A₆) and the residual deformation (A₇, and higher coefficients). In some embodiments, the target paraboloid deformation A₄ can be selected with at least an excess magnitude Ag over the minimum needed to overcompensate for the deformation of the composite structure, e.g.,

$${\tilde{A}}_{4} {Z}_{4} ( ρ , ϕ ) + h ( r , ϕ ) > {A}_{E} {Z}_{4} ( ρ , ϕ ) .$$

The excess magnitude Ag can be empirically selected and can depend on the specific material of the SCL.

Once the target paraboloid deformation Ã₄ has been determined, the thickness of the mask d can be selected using a calibration data that tabulates or otherwise defines a function d=ƒ(Ã₄). In some embodiments, the function ƒ(Ã₄) can be a nonlinear function. In some embodiments, the function ƒ(Ã₄) can be a linear function, d=αÃ₄, with a coefficient of proportionality α determined based on mathematical modeling of elastic equations for specific mask material(s), using empirical calibration, or any combination thereof. In some embodiments, operations of block 560 can include at least some operations of method 600 disclosed below.

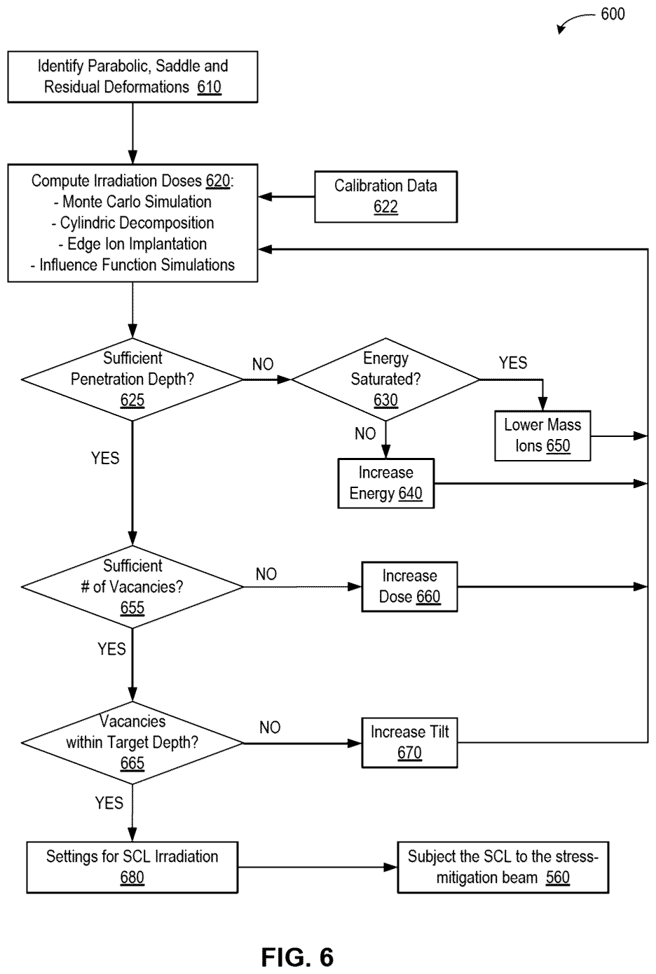

FIG. 6 is a flowchart illustrating an example method 600 of determining settings for irradiation by a stress-modification beam, in accordance with at least one embodiment, in accordance with at least one embodiment. Method 600 can be performed as part of blocks 550-560 of method 500. At block 610, method 600 can include identifying some or all of a parabolic deformation (e.g., Zernike coefficients A₄), saddle deformation (e.g., Zernike coefficients A₅, A₆), and the residual deformation (e.g., Zernike coefficients A₇, A₈ . . . ) of a sample, e.g., using profilometry measurements. In some embodiments, the sample can include the composite structure (e.g., made of the first substrate and the second substrate, as illustrated in FIG. 2K).

At block 620, method 600 can continue with computing irradiation doses n(\vec{r}) for the SCL deposited on the sample. Operations of block 620 can include one or more techniques for determining n(\vec{r}). In some embodiments, irradiation doses n(\vec{r}) can be computed using Monte Carlo simulations. In some embodiments, irradiation doses n(\vec{r}) can be computed using cylindrical decomposition of h_{WF}(\vec{r}).

In some embodiments, irradiation doses n(\vec{r}) can be computed (and then applied at block 560) for selected edge regions of the SCL. More specifically, operations of block 620 can include identifying principal axes (directions) and a magnitude of a saddle deformation, e.g., σⱼₖ∝cos (2ϕ+α), and further identifying edge regions of the SCL as targets for stress-mitigation irradiation to achieve efficient flattening of the sample. Further (finer) reduction of stresses of the sample can be achieved by irradiation into a broader area of the SCL, e.g., to mitigate a residual deformation remaining after edge irradiation.

In some embodiments, the irradiation doses n(\vec{r}) can be computed using an influence function G(\vec{r}; \vec{r}′), also known as the Green's function, which characterizes a response (e.g., deformation) of the wafer at a point \vec{r} of the sample as caused by a point-like force applied at a point \vec{r}′of the sample. In some embodiments, the influence function G(\vec{r}; \vec{r}′) can be determined from computational simulations or analytical calculations. In some embodiments, the influence function can be determined from one or more experiments, which can include performing ion implantation into a film deposited on a reference sample. In some embodiments, a combination of multiple techniques of determining the influence function G(\vec{r}; \vec{r}′) can be used.

As a way of example, the Monte Carlo simulations for a structure (e.g., wafer with films and a mask deposited thereon) can be performed for specific materials of the sample (e.g., silicon wafer(s), glass wafers, stacks of ON layers or Si/SiGe layers, and/or the like) and for a specific thickness of the sample. An initial Monte Carlo simulation can be performed for baseline (default) conditions of beam irradiation (e.g., default settings of an ion implantation apparatus or a light-emitting apparatus). The baseline conditions can include a default type of particles (ions, photons, electrons), a default energy of particles, a default dose of particles to be directed to the mask (e.g., a default velocity of scanning and a default scanning pattern), and the like.

In some embodiments, various techniques of irradiation dose computations can use calibration data 622 collected for actual irradiation performed for various types of the irradiation beams, energies of the irradiation beams, types and materials of structures being irradiated, angles of beam incidence on the structures, and/or the like. In some embodiments, calibration data 622 can be statistically preprocessed. For example, various measurements can be collected for multiple wafer/film/mask materials, types of particles, angles of incidence, and/or other parameters. The statistically processed measurements can be stored (e.g., in a memory of a processing device performing computation of the irradiation doses) in the form of probability distributions of various quantities, including but not limited to:
distribution of the density of ion implantation with depth for different ion types, ion energies, angles of incidence;
distribution of the number of vacancies produced at different depths (per unit of length of travel of the ions) for different types of irradiation particles (ions, photons, electrons), particle energies, and angles of incidence;
distribution of stresses created by irradiation beams for different beam intensities and durations; and/or the like.

Performing irradiation dose computations of block 620 can include sampling from the stored distributions and identifying a likelihood that a target stress mitigation will be achieved with the default settings of conditions of beam irradiation of an SCL of a given type and thickness. Method 600 can include several verification operations designed to determine whether the target stress can be achieved without detrimentally affecting properties of the wafer/films. For example, at block 625, method 600 can include verifying if the penetration depth of the selected (e.g., default) type of particles is sufficient. For example, the penetration depth is to be at least a certain fraction of the thickness of the mask, e.g., 20%, 30%, 50%, 80%, or more of that thickness. In some embodiments the penetration depth can be up to 100% of the thickness. If the energy is insufficient, method 600 can include checking, at block 630, if the irradiation beam source is capable of outputting particles of a higher energy. If higher energies are available, method 600 can continue with increasing the energy of the particles (block 640) and repeating irradiation dose computations of block 620 for the increased energy. If the maximum energy of the irradiation beam source has already been reached, method 600 can continue with replacing (at block 650) ions with ions of a different type (e.g., if an ion beam is used for irradiation), e.g., replacing Silicon ions with Boron, Carbon, Fluorine, etc., ions, and repeating Monte Carlo simulations for the ions of the new type.

At block 655, method 600 can include verifying whether the number of expected formed vacancies is sufficient. To verify sufficiency, method 600 can assess stress mitigation caused by formed vacancies. In one embodiment, method 600 can begin at some value of stress in the SCL, e.g., −3.0 GPa or some other suitable value (negative sign indicating compressive stress) and use beam irradiation to mitigate this stress towards a neutral point, 0.0 GPa at various locales of the SCL.

If the number of vacancies is insufficient, method 600 can include increasing a dose of particles (at block 660) and repeating irradiation dose computations of block 620 for the increased dose.

At block 665, method 600 can include verifying that the vacancies are going to be placed within a target depth, e.g., the thickness d of the film or a certain fraction of the film, such as 0.8 d, 0.7 d, 0.5 d, or some other value empirically set to prevent particles from penetrating into the substrates/films and affecting properties of the substrates/films. If the vacancies are to be formed at depths that exceed the target depth, method 600 can include (at block 670) increasing an angle of incidence (e.g., by tilting the irradiation beam) to keep vacancies (as well as substitution impurities) to a shallower region of the mask.

Blocks 620-670 can be repeated multiple times until irradiation dose computations of block 620 are determined to be sufficient that the desired stress mitigation can be achieved, e.g., that the reduction in the tensile stress of the SCL is such that the deformation of the sample is eliminated or at least reduced to an acceptable tolerance. The final settings for the SCL irradiation (block 680) determined from irradiation dose computations can then be used for irradiation of the SCL with the stress-modification beam (at block 560).

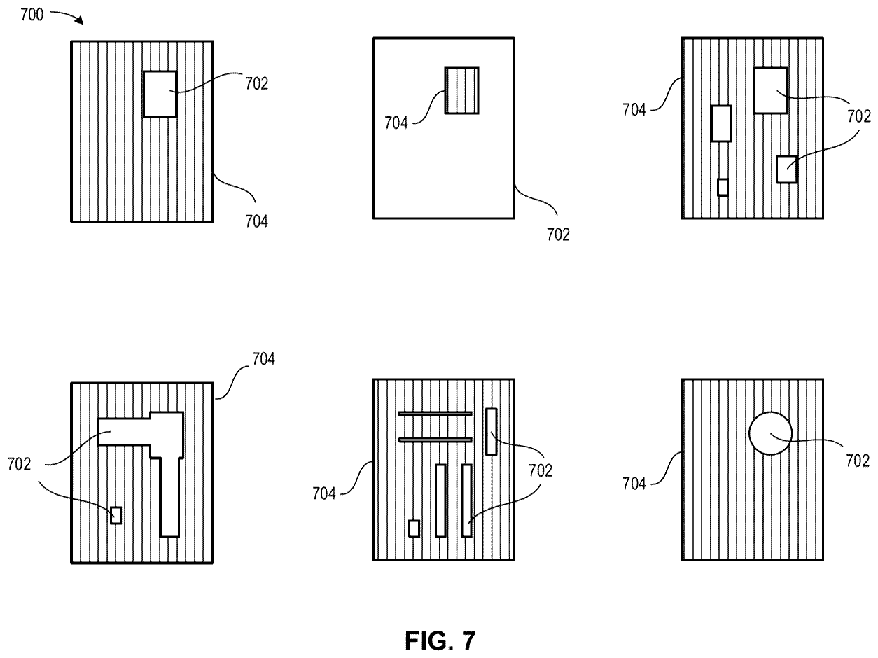

FIG. 7 illustrates schematically example protective mask patterns that can be uses for mitigation of local stresses and deformations in complex multi-substrate manufacturing structures, according to at least one embodiment. FIG. 7 depicts individual (e.g., die-size) tiles 700 of a protective mask (e.g., protective mask 208, with reference to FIGS. 2C-2E). Tile 700 can be repeated any number of times across the area of the protective mask. Tile 700 can include one or more opening portions 702 (depicted with no shading), which admit access of chemicals, beams, and/or other agents to the underlying films and structures, and closed shaded portions 704, which prevent such access.

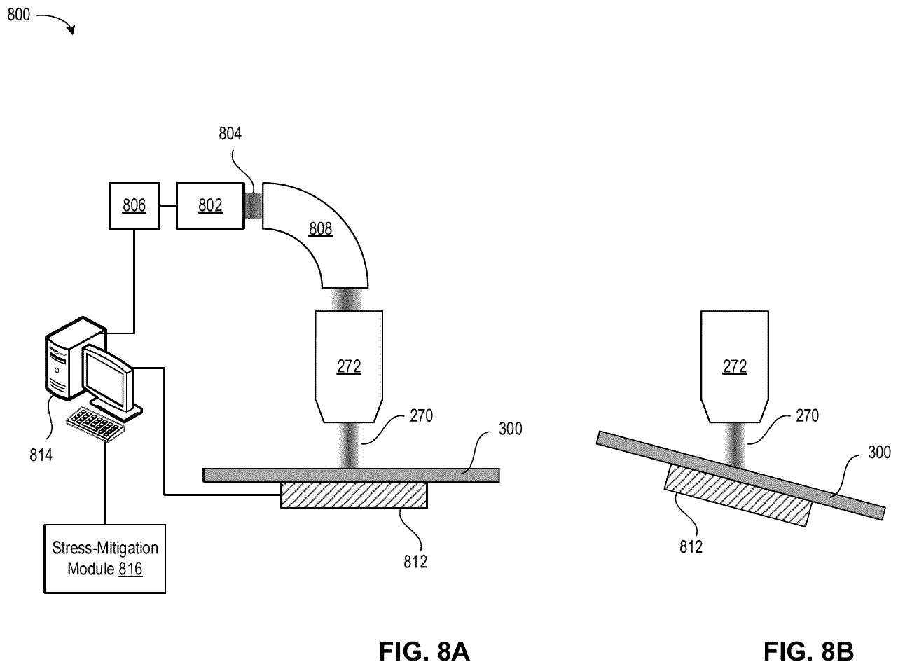

FIG. 8A illustrates schematically an irradiation system 800 capable of performing irradiation of stress compensation layers, according to at least one embodiment. Irradiation system 800 can include collimating and focusing column 272 of FIG. 2K. Irradiation system 800 can further include a beam source 802 for producing a source beam 804. Beam source 802 can include a chamber for generating ions (e.g., a plasma chamber), a light source for generating photons (e.g., a laser, laser diode, lamp, etc.), a heated filament for producing electrons, and/or any other source for the particles of a type deployed in specific stress-mitigation techniques of the instant disclosure. Beam source 802 can be powered by a power element 806 and can include an extraction electrode assembly (not shown). Irradiation system 800 can include a mass spectrometer 808 (e.g., in the instances where beam source 802 produces charged particles, such as electrons or ions) and a collimating and focusing column 272. Collimating and focusing column 272 can direct stress-modification beam 270 to sample 300. Sample 300 can be supported by a support stage 812. In some embodiments, support stage 812 and sample 300 can remain stationary during irradiation of sample 300 by stress-modification beam 270 while components of irradiation system 800 can be repositioned relative to sample 300. In some embodiments, irradiation system 800 can be stationary while support stage 812 can reposition sample 300. In some embodiments, stress-modification beam 270 can have intensity (e.g., light intensity) that is modulated by changing intensity of beam source 802 and/or placing a partially absorbing or partially reflecting material at some location between beam source 802 and sample 300. This enables delivery of local irradiation doses n(x, y) to various locations of sample 300. Scanning with stress-modification beam 270 can occur along multiple directions, e.g., along x-axis and along y-axis according to any suitable predetermined pattern, e.g., back-and forth along x-axis, in a spiral pattern, and so on. In various embodiments, stress-modification beam 270 can be scanned with a frequency of several Hz, tens of Hz, hundreds of Hz, thousands of Hz, or more.

Operations of irradiation system 800 can be controlled by a controller 814, which can include any suitable computing device, microcontroller, or any other processing device having a processor, e.g., a central processing unit (CPU), a field-programmable gate array (FPGA), an application-specific integrated circuit (ASIC), and/or the like, and a memory device, e.g., a random-access memory (RAM), read-only memory (ROM), flash memory, and/or the like or any combination thereof. Controller 814 can control operations of power element 806, support stage 812, and/or various other components and modules of irradiation system 800. Controller 814 can include a stress-mitigation module 816 capable of performing simulations that determine a target intensity of stress-modification beam 270 to be used to mitigate various wafer deformations. In some embodiments, as illustrated in FIG. 8B, support stage 812 can impart a tilt, e.g., in one or two spatial directions to first substrate 102 to change an angle of incidence of stress-modification beam 270 relative to sample 300. In some embodiments, instead of tilting first substrate 102, controller 814 can cause a tilt of stress-modification beam 270 relative to sample 300.

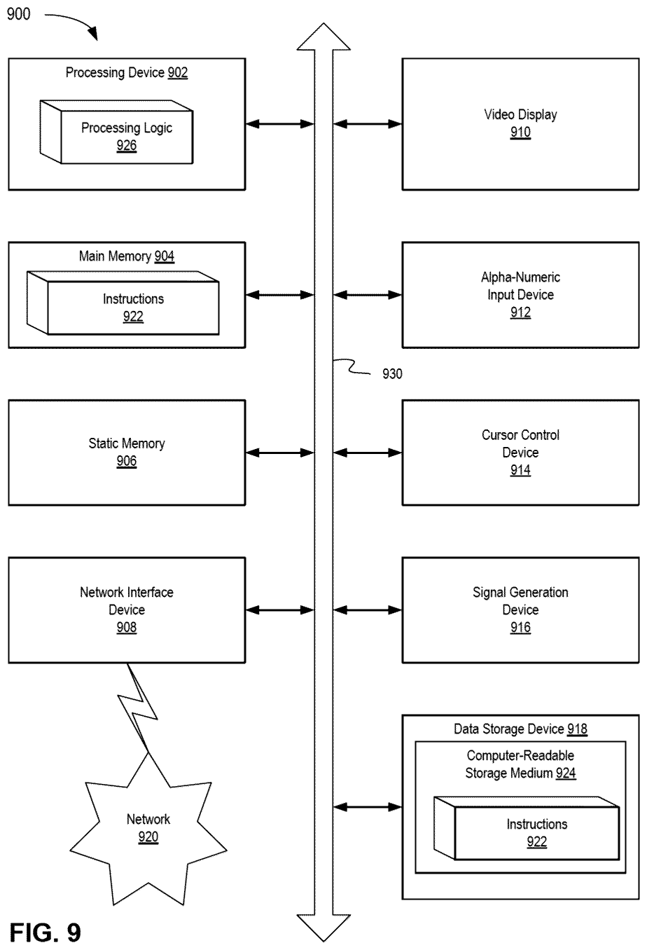

FIG. 9 depicts a block diagram of an example computer system 900 capable of supporting operations of the present disclosure, according to at least one embodiment. In various illustrative examples, example computer system 900 may be or include controller 814 of FIG. 8. Example computer system 900 may be connected to other computer systems in a LAN, an intranet, an extranet, and/or the Internet. Computer system 900 may operate in the capacity of a server in a client-server network environment. Computer system 900 may be a personal computer (PC), a set-top box (STB), a server, a network router, switch or bridge, or any device capable of executing a set of instructions (sequential or otherwise) that specify actions to be taken by that device. Further, while only a single example computer system is illustrated, the term “computer” shall also be taken to include any collection of computers that individually or jointly execute a set (or multiple sets) of instructions to perform any one or more of the methods discussed herein.

Example computer system 900 may include a processing device 902 (also referred to as a processor or CPU), a main memory 904 (e.g., read-only memory (ROM), flash memory, dynamic random access memory (DRAM) such as synchronous DRAM (SDRAM), etc.), a static memory 906 (e.g., flash memory, static random access memory (SRAM), etc.), and a secondary memory (e.g., a data storage device 918), which may communicate with each other via a bus 930.

Processing device 902 represents one or more general-purpose processing devices such as a microprocessor, central processing unit, or the like. More particularly, processing device 902 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 902 may also be one or more special-purpose processing devices such as an application specific integrated circuit (ASIC), a field programmable gate array (FPGA), a digital signal processor (DSP), network processor, or the like. In accordance with one or more aspects of the present disclosure, processing device 902 may include a processing logic 926 configured to execute instructions (e.g., instructions 922) implementing example method 500 of mitigation of wafer stress and deformation using front-side irradiation and/or method 600 of determining front-side irradiation parameters, in accordance with at least one embodiment.

Example computer system 900 may further comprise a network interface device 908, which may be communicatively coupled to a network 920. Example computer system 900 may further comprise a video display 910 (e.g., a liquid crystal display (LCD), a touch screen, or a cathode ray tube (CRT)), an alphanumeric input device 912 (e.g., a keyboard), a cursor control device 914 (e.g., a mouse), and an acoustic signal generation device 916 (e.g., a speaker).

Data storage device 918 may include a computer-readable storage medium (or, more specifically, a non-transitory computer-readable storage medium) 924 on which is stored one or more sets of executable instructions 922. In accordance with one or more aspects of the present disclosure, executable instructions 922 may comprise executable instructions implementing example method 500 of mitigation of wafer stress and deformation using front-side irradiation and/or method 600 of determining front-side irradiation parameters, in accordance with at least one embodiment.

Executable instructions 922 may also reside, completely or at least partially, within main memory 904 and/or within processing device 902 during execution thereof by example computer system 900, main memory 904 and processing device 902 also constituting computer-readable storage media. Executable instructions 922 may further be transmitted or received over a network via network interface device 908.

While the computer-readable storage medium 924 is shown in FIG. 9 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method comprising:
forming a deformation-accommodating layer (DAL) on a target substrate, wherein the target substrate comprises one of:
a first substrate supporting one or more manufactured features, or a second substrate;
removing one or more portions of the DAL;
causing the first substrate and the second substrate to form a composite structure; and
thinning the first substrate to expose at least a subset of the one or more manufactured features, wherein the one or more portions of the DAL are removed to cause, responsive to the thinning, a deformation of the composite structure to be reduced.

2. The method of claim 1, wherein the one or more manufactured features comprise at least one of:
one or more transistors, or
an interconnect circuitry.

3. The method of claim 1, wherein forming the DAL on the target substrate comprises:
placing a DAL material on the target substrate;
forming a protective mask on the DAL material; and
using the protective mask to remove the one or more portions of the DAL.

4. The method of claim 3, wherein the protective mask comprises one or more openings, and wherein using the protective mask to remove the one or more portions of the DAL comprises:
exposing, through the one or more openings, the one or more portions of the DAL to at least one of:
an etch environment,
an ashing environment,
an environment comprising one or more radicals, or
an environment comprising one or more solvents.

5. The method of claim 3, wherein the protective mask comprises one or more openings, and wherein using the protective mask to remove the one or more portions of the DAL comprises:
exposing, through the one or more openings of the protective mask, the one or more portions of the DAL to at least one of:
a beam of ions,
a beam of photons, or
a beam of electrons.

6. The method of claim 3, further comprising:
removing, prior to causing the first substrate and the second substrate to form the composite structure, the protective mask.

7. The method of claim 3, wherein the protective mask comprises a pattern of openings correlated with a pattern of deformation of the first substrate, the pattern of deformation caused by the one or more manufactured features.

8. The method of claim 1, wherein removing the one or more portions of the DAL creates a profile of the DAL comprising at least one of:
one or more elevated portions of a surface of the DAL, or
one or more depressed portions of the surface of the DAL.

9. The method of claim 1, wherein the DAL comprises an adhesion material facilitating formation of the composite structure from the first substrate and the second substrate.

10. The method of claim 1, wherein the DAL comprises at least one of:
a silicon oxide,
a silicon nitride,
a silicon-carbon nitride, or
an aluminum nitride.

11. The method of claim 1, wherein the DAL is formed using one or more of:
contact photolithography,
proximity photolithography,
projection photolithography,
imprint lithography, or
digital lithography.

12. The method of claim 1, wherein the thinning of the first substrate is performed using one or more of:
grinding,
chemical-mechanical polishing,
etching, or
exposure to a hydrofluoric acid.

13. The method of claim 1, further comprising:
forming a stress-compensation layer (SCL) on the second substrate; and
subjecting the SCL to a stress-modification beam to further reduce the deformation of the composite structure.

14. The method of claim 1, wherein removing the one or more portions of the DAL comprises:
obtaining optical inspection data characterizing a profile of deformation of the first substrate; and
identifying, using the optical inspection data, the one or more portions of the DAL to be removed.

15. A system comprising:
a memory; and
a processing device communicatively coupled to the memory, wherein the processing device is to cause performance of operations comprising:
forming a deformation-accommodating layer (DAL) on a target substrate, wherein the target substrate comprises one of:
a first substrate supporting one or more manufactured features, or
a second substrate;
removing one or more portions of the DAL;
causing the first substrate and the second substrate to form a composite structure; and
thinning the first substrate to expose at least a subset of the one or more manufactured features, wherein the one or more portions of the DAL are removed to cause, responsive to the thinning, a deformation of the composite structure.

16. The system of claim 15, wherein forming the DAL on the target substrate comprises:
placing a DAL material on the target substrate;
forming a protective mask on the DAL material; and
using the protective mask to remove the one or more portions of the DAL.

17. The system of claim 16, wherein the protective mask comprises one or more openings, and wherein using the protective mask to remove the one or more portions of the DAL comprises:
exposing, through the one or more openings, the one or more portions of the DAL to at least one of:
an etch environment,
an ashing environment,
an environment comprising one or more radicals, or
an environment comprising one or more solvents.

18. The system of claim 16, wherein the protective mask comprises one or more openings, and wherein using the protective mask to remove the one or more portions of the DAL comprises:
exposing, through the one or more openings of the protective mask, the one or more portions of the DAL to at least one of:
a beam of ions,
a beam of photons, or
a beam of electrons.

19. The system of claim 16, wherein the protective mask comprises a pattern of openings correlated with a pattern of deformation of the first substrate, the pattern of deformation caused by the one or more manufactured features.

20. A semiconductor manufacturing system comprising:
one or more processing chambers to:
form a deformation-accommodating layer (DAL) on a target substrate, wherein the target substrate comprises one of:
a first substrate supporting one or more manufactured features, or
a second substrate;
remove one or more portions of the DAL;
cause the first substrate and the second substrate to form a composite structure; and
thin the first substrate to expose at least a subset of the one or more manufactured features, wherein the one or more portions of the DAL are removed to cause, responsive to the thinning. a deformation of the composite structure.
